(19) United States
(12) Patent Application Publication
(10) Pub. No.: US 2017/0223441 A1
(43) Pub. Date: Aug. 3, 2017

(54) Microphone Arrangement which has an Enlarged Opening and is Decoupled from the Cover

(71) Applicant: EPCOS AG, München (DE)

(72) Inventors: Kurt RASMUSSEN, Herlev (DK); Pirmin Hermann Otto ROMBACH, Kongens Lyngby (DK)

(21) Appl. No.: 15/311,090

(22) PCT Filed: Apr. 28, 2015
(86) PCT No.: PCT/EP2015/059203

§ 371 Date: Nov. 14, 2016

(30) Foreign Application Priority Data
May 14, 2014 (DE) 10 2014 106 818.1

(51) Int. Cl. H04R 1/08; H04R 19/00; B81B 7/00; H04R 19/04

(52) U.S. Cl. CPC H04R 1/086; H04R 19/04; H04R 19/005; B81B 7/0058; H04R 2201/003; B81B 2201/0257; B81B 2207/012

(57) ABSTRACT

A microphone arrangement having an enlarged opening is disclosed. In an embodiment, the microphone includes a substrate, a transducer element arranged on the substrate, a cover having an opening, wherein the opening of the cover completely covers the transducer element and a sound separation fixing the cover to the transducer element.

This patent application is a national phase filing under section 371 of PCT/EP2015/059203, filed Apr. 28, 2015, which claims the priority of German patent application 10 2014 106 818.1, filed May 14, 2014, each of which is incorporated herein by reference in its entirety.

### TECHNICAL FIELD

The present invention relates to a microphone. This may involve, in particular, a semiconductor capacitor microphone.

### BACKGROUND

Such a microphone comprises a transducer element, which must be encapsulated in a housing. In order to enable a good recording quality in the case of such a microphone, a back volume that is as large as possible is required since the sensitivity of the microphone for the recording of sound waves is improved by a large back volume. Furthermore, the microphone should be configured such that it has the highest possible signal-to-noise ratio (SNR).

DE 102004011148 B3 discloses a microphone in which a microphone chip is encapsulated by means of a cover and a sound seal. In the case of this microphone, however, strong mechanical couplings between cover and microphone chip occur which can adversely affect the functioning of the microphone chip and which lead to a temperature-dependent behavior of the system.

A different encapsulation of a MEMS microphone is known from US 2011/0274299 A1. However, this microphone has a comparatively small back volume, as a result of which the sensitivity of the microphone is adversely affected.

### SUMMARY OF THE INVENTION

Embodiment of the invention provide a microphone that comprises a substrate, a transducer element arranged on the substrate, a cover having an opening, wherein the opening of the cover completely covers the transducer element and a sound separation, which fixes the cover to the transducer element.

Since the opening of the cover completely covers the transducer element, a deformation of the cover cannot directly affect the transducer element. Rather, the sound separation arranged between the cover and the transducer element provides for a mechanical decoupling between the transducer element and the cover. As a result, the transducer element is protected significantly better against a situation in which its mechanical mechanism might be adversely affected by deformations of the cover.

The transducer element can be a MEMS microphone. In particular, a capacitor microphone comprising a movable membrane and a fixed backplate can be involved. The transducer element can be configured to the effect that soundwaves can lead to alterations of a capacitance between the membrane and the backplate and be measured in this way.

The microphone can be a top port microphone. Accordingly, the microphone can comprise a sound entrance opening arranged on a side facing away from the substrate.

The sound separation can fix the cover to the transducer element directly, in particular. Accordingly, the sound separation is arranged between the cover and the transducer element. The sound separation is characterized by a sound-proof closing of an interspace between the cover and the transducer element.

The opening of the cover is sound-transmissive, in particular. Accordingly, the opening of the cover can be connected to a sound entrance opening of the transducer element in such a way that the sound entrance opening of the transducer element is acoustically connected to surroundings of the microphone via the opening in the cover.

The sound separation provides for a mechanical decoupling between the cover and the transducer element. Forces that act on the cover, for example during the incorporation of the microphone into a housing, wherein a sealing ring is pressed on the cover, are thus absorbed for the most part by the sound separation and do not act on the transducer element at all or act thereon at least to a greatly damped extent. This ensures that the mechanical properties of the transducer element are not adversely affected by such forces. An alteration of the mechanical properties of the transducer element is undesired since systematic measurement errors could occur in this case.

Temperature fluctuations can also lead to deformations of the cover. Since such deformations can also be absorbed by the sound separation, the temperature sensitivity of the entire microphone is significantly improved by the sound separation. Since deformations of the cover on account of temperature fluctuations cannot act directly on the transducer element, the microphone now reacts significantly less to temperature fluctuations and can thus be used reliably over a much greater temperature range.

The wording “the opening of the cover completely covers the transducer element” should be understood here as follows: If the cover and the transducer element were projected onto the substrate, then the transducer element and the cover would not overlap. Consequently, an overlap of the cover and the transducer element does not occur in the event of a projection onto the substrate. In other words, if the microphone is viewed from above, i.e. from a perspective perpendicular to the substrate, then the opening of the cover is of such a size and arranged in such a way that the transducer element is arranged completely in the opening. When the microphone is viewed from a perspective perpendicular to the substrate, therefore, there is no overlap of the transducer element and the regions of the cover which do not constitute the opening.

The transducer element can form a front volume and a back volume, wherein the front volume is suitable for communicating in terms of pressure with surroundings of the microphone via the opening of the cover, and wherein the cover and the sound separation are arranged such that the cover, the sound separation, the transducer element and the substrate enclose the back volume of the transducer element. In particular, the cover, the sound separation, the transducer element and the substrate enclose a space that forms the back volume.

Consequently, the cover and the sound separation can effectively enlarge the back volume of the transducer element. In particular, now the entire interior of the cover minus the volume of the transducer element, and if appropriate of further components arranged within the cover, can be utilized as back volume for the transducer element. Consequently, a large back volume can be provided, which leads to a significant improvement in the sensitivity of the microphone. The back volume is a space configured such that the pressure prevailing in the back volume is not variable by soundwaves.

In the membrane it is possible to provide an opening having a small diameter, via which a pressure equalization between the front volume and the back volume occurs. However, the opening is designed in such a way that it has such a high acoustic impedance that soundwaves do not penetrate into the back volume. The back volume of the transducer element is thus a reference volume that is acoustically separated from the front volume.

In one exemplary embodiment, the cover consists of metal. However, the cover can also consist of any other conductive material.

The sound separation can comprise a material having a lower modulus of elasticity than the cover. Accordingly, the sound separation can be softer than the cover. Consequently, the sound separation will deform more easily than the cover under the action of a force, and absorb this force better. This ensures that forces that act on the cover are damped by the sound separation and can thus act on the transducer element only to a reduced extent.

The sound separation can comprise an adhesive. In particular, the sound separation can comprise cured silicone adhesive. Cured silicone adhesive is particularly suited since it can provide for a good sound insulation of the interspace between the cover and the transducer element and moreover is very soft, such that it can absorb well forces acting and thus mechanically separates the cover and the transducer element from one another. However, other adhesives having comparable properties can also be used.

The cover can have a top side arranged parallel to the substrate, wherein the opening of the cover is arranged in the top side.

The top side of the cover can have a first region and a second region, wherein the opening can be arranged in the first region, and wherein the first region can be at a smaller distance from the substrate than the second region.

The second region can be directly adjacent to a side wall of the cover. The first region can be directly adjacent to the second region. The first region can be an inner region of the top side, and the second region can be an outer region of the top side. The first region can be offset relative to the second region toward the substrate. Accordingly, a step can be formed between the first region and the second region. The offset between the first and second regions can simplify the application and curing of an adhesive, wherein the adhesive can be cured to form the sound separation.

In one exemplary embodiment, the surface of the cover can have a depression facing toward the substrate. Said depression can be configured for example in the shape of a trench, in a wavy fashion or in a meandering fashion. The depression can be arranged in a second region of the cover. The depression can contribute to the further mechanical decoupling between the remaining region of the cover and the transducer element. In particular, the depression can form a mechanical weak point of the cover, such that forces that act on the cover initially lead to a deformation of the depression and, accordingly, are not forwarded to further elements connected to the cover, such as e.g. the sound separation and, via the sound separation, the transducer element.

The sound separation can comprise a film that at least partly covers the cover and the transducer element. The film can also cover the cover to an extent such that only the opening of the cover is free of the film. The film can consist of a soft material, in particular, such that a sound separation having a low modulus of elasticity is produced. A good mechanical decoupling of the cover and the transducer element can be ensured as a result.

Such a film is used in various encapsulation methods for MEMS microphones. Therefore, in accordance with this exemplary embodiment, the film can be utilized both for encapsulation and for mechanical fixing of the cover to the transducer element.

The film can consist of a polymer, for example. This may be a soft polymer, in particular, which enables both a good sound insulation and a good mechanical decoupling.

Furthermore, a metal layer can be arranged above the film. The metal layer can be arranged on the film directly, in particular.

Furthermore, the transducer element can have a sound entrance opening that is free of the sound separation. Accordingly, the sound separation does not impede the entrance of sound through the sound entrance opening of the transducer element.

In an alternative exemplary embodiment, the sound entrance opening can be partly covered by the sound separation. In this case, the sound separation can form a protection for the sound entrance opening and prevent dirt from penetrating into the transducer element through the sound entrance opening. The sound separation can have for example a grille-shaped region that partly covers the sound entrance opening.

Furthermore, a sound-transmissive protective grille can be arranged above the opening of the cover. Such a sound-transmissive protective grille protects the microphone against the penetration of dirt. Furthermore, the protective grille can be produced from a conductive material and be configured to protect the transducer element against electrostatic discharges (ESD=electrostatic discharge) and electromagnetic interference radiation (EMI=electromagnetic interference).

### BRIEF DESCRIPTION OF THE DRAWINGS

The microphone and preferred exemplary embodiments are explained in greater detail below with reference to the figures.

FIG. 1 shows a first exemplary embodiment of a microphone.

FIG. 2 shows a second exemplary embodiment of the microphone.

FIG. 3 shows a third exemplary embodiment of the microphone.

FIGS. 4a to 4e show different steps of a method for producing the microphone in accordance with the second exemplary embodiment.

FIG. 5 shows a fourth exemplary embodiment of the microphone.

FIGS. 6a to 6i show different steps of a method for producing the microphone in accordance with the fourth exemplary embodiment.

FIG. 7 shows a fifth exemplary embodiment of the microphone.

### DETAILED DESCRIPTION OF ILLUSTRATIVE EMBODIMENTS

FIG. 1 shows a first exemplary embodiment of a microphone 1. The microphone 1 comprises a transducer element 2. The transducer element 2 comprises a membrane 3 and a fixed backplate 4. A voltage is applied between the membrane 3 and the backplate 4, such that the membrane 3 and the backplate 4 form a capacitor. The capacitance of this capacitor is variable depending on a detected sound.

The transducer element 2 forms a front volume 5 and a back volume 6. The front volume 5 is acoustically connected to surroundings of the microphone 1. The transducer element 2 has a sound entrance opening 7, via which the front volume 5 is acoustically connected to the surroundings and by which sound can be passed to the membrane 3. The back volume 6 of the transducer element 2 is a reference volume that is acoustically separated from the front volume 5. The transducer element 2 is suitable for measuring a difference between the sound pressure in the front volume 5 and the sound pressure in the back volume 6.

The transducer element 2 is arranged on a substrate 8. The transducer element 2 is fixed on the substrate by means of solder bumps 9. Furthermore, the microphone 1 comprises a further component 10. This may be, for example, a component suitable for the signal processing of the signals detected by the transducer element 2. In particular, a chip having an ASIC (application-specific integrated circuit) may be involved.

Furthermore, the microphone 1 comprises a cover 11. The cover 11 is fixed on the substrate 8 by an adhesive 12, wherein the adhesive 12 can be conductive. The cover 11 consists of metal. The cover 11 has an opening 13, wherein the opening 13 of the cover 11 completely covers the transducer element 2. The opening 13 is illustrated by a dotted line in FIG. 1.

The microphone 1 furthermore comprises a sound separation 14. The sound separation 14 is arranged between the cover 11 and the transducer element 2 in such a way that it fixes the cover 11 to the transducer element 2. In accordance with the first exemplary embodiment, the sound separation 14 comprises an adhesive. In particular, the sound separation 14 comprises a cured silicone adhesive.

The sound separation 14 provides for a sound-proof connection between the transducer element 2 and the cover 11. The sound separation 14, the transducer element 2, the cover 11 and the substrate 8 enclose a space that forms the back volume 6 of the transducer element 2. The back volume 6 is formed by the sound separation 14, the transducer element 2, the cover 11 and the substrate 8.

The back volume 6 formed in this way is significantly larger than a back volume that is delimited only by the transducer element 2 and the substrate 8. The enlarged back volume 6 leads to an improvement in the measurement accuracy of the transducer element 2. In particular, a large back volume 6 makes it possible that the transducer element 2 can reliably resolve and measure even small pressure differences between the front volume 5 and the back volume 6.

The sound separation 14 comprises a material having a lower modulus of elasticity than a material of the cover 11. Accordingly, if a force is exerted on the microphone 1 in the direction of the substrate 8, then firstly the cover 11 and the sound separation 14 deform under this force, while the transducer element 2 remains largely undeformed.

The microphone 1 can be incorporated for example into the housing of a cellular phone (not shown), wherein a top side of the microphone 1 facing away from the substrate 8 is pressed against an inner side of the housing. Since the sound separation 14 consists of a soft material, it can deform under the action of the forces occurring in the process and can thus absorb the forces occurring. This prevents the force from being forwarded directly to the transducer element 2. Accordingly, the forces occurring do not act, or act at least only to a greatly damped extent, on the transducer element 2 and therefore do not alter or at least only slightly alter the mechanical properties of the transducer element 2.

The sound separation 14 furthermore provides for a mechanical decoupling of the cover 11 from the transducer element 2. Even if a mechanical deformation of the cover 11 occurs, it does not directly lead to an influencing of the functionality of the transducer element 2. Rather the sound separation 14 will absorb the forces occurring in the event of a deformation of the cover 11 and will not pass these forces on, or will pass them on at least only to a greatly damped extent, to the transducer element 2.

A mechanical deformation of the cover 11 can occur for example during the incorporation of the microphone into a housing. In this case, for example, the cover 11 can be pressed against a sealing ring.

Temperature fluctuations can also lead to mechanical deformations of the cover 11. The mechanical decoupling between the cover 11 and the transducer element 2 by the sound separation 14 accordingly ensures that the microphone 1 functions stably over a larger temperature range. The temperature dependence of the microphone 1 is thus reduced.

Furthermore, a sound-transmissive protective grille 15 is arranged above the opening 13 of the cover 11. The protective grille 15 is configured to prevent dust from penetrating into the microphone 1. Furthermore, the protective grille 15 is produced from a conductive material and configured to protect the microphone 1 against electrostatic discharges and electromagnetic interference radiation.

The cover 11 has a side wall 16 and a top side 17. The side wall 16 stands on the substrate 8 and connects the substrate 8 to the top side 17. In this case, the side wall 16 can be arranged for example perpendicular to the substrate 8. Alternatively, side wall 16 and substrate 8 can form a different angle than 90°. The top side 17 is arranged parallel to the substrate 8 and is situated at a distance from the substrate 8. The opening 13 of the cover 11 is arranged in the top side 17. The top side 17 of the cover 11 is flat.

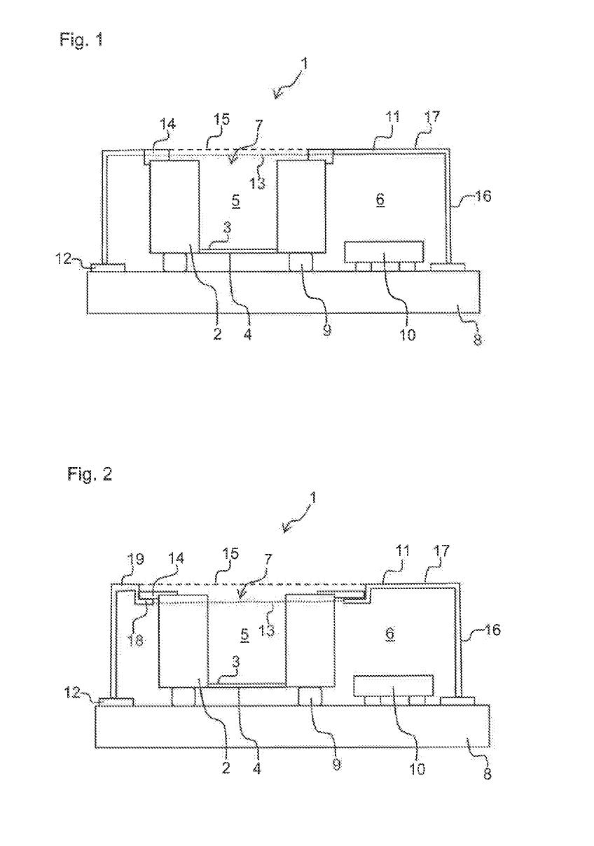

FIG. 2 shows a second exemplary embodiment of the microphone 1. The second exemplary embodiment differs from the first exemplary embodiment shown in FIG. 1 with regard to the shape of the cover 11.

In the second exemplary embodiment, the top side 17 of the cover 11 has a first region 15 and a second region 19. The second region 19 of the top side 17 is directly adjacent to the side walls 16. The first region 18 of the top side 17 is directly adjacent to the second region 19 and has the opening 13. The first region 18 of the top side 17 is arranged at a smaller distance from the substrate 8 than the second region 19. The first region 18 and the second region 19 are in each case parallel to the substrate 8. Accordingly, the first region 18 is offset toward the interior of the microphone 1. Consequently, a step is formed between the first region 18 and the second region 19.

This configuration of the cover 11 simplifies the application of the adhesive that is cured to form the sound separation 14. In the first exemplary embodiment shown in FIG. 1, the adhesive can lead, under certain circumstances, to a beadlike projection that projects from the microphone 1 in a direction away from the substrate 8. The fact that the adhesive in accordance with the second exemplary embodiment is applied into the inwardly offset first region 18 prevents the adhesive from projecting outward. A microphone 1 having a smooth top side is thus produced.

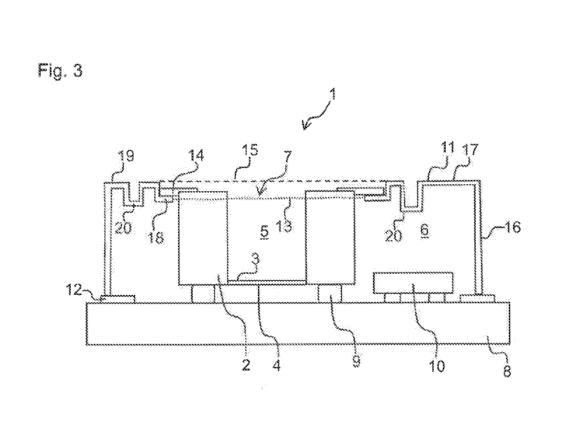

FIG. 3 shows a third exemplary embodiment of the microphone 1. In the exemplary embodiment shown in FIG. 3, the top side 17 of the cover 11 has a depression 20 facing toward the substrate 8. Said depression 20 is configured in the shape of a trench. However, differently shaped depressions are also conceivable. By way of example, the depression 20 can have a meandering profile.

The depression 20 is arranged in the second region 19. The depression 20 provides for a further improvement in the mechanical decoupling between the cover 11 and the transducer element 2. Deformations of the cover 11 in the second region 19 and in the side walls 16 can be partly absorbed by deformations of the depression 20 and, accordingly, are not completely passed on to the sound separation 14 and the transducer element 2. The cover 11 is thus configured likewise to absorb forces and thereby to prevent these forces from influencing the mechanism of the transducer element 2.

Such a depression 20 is also compatible with the first exemplary embodiment.

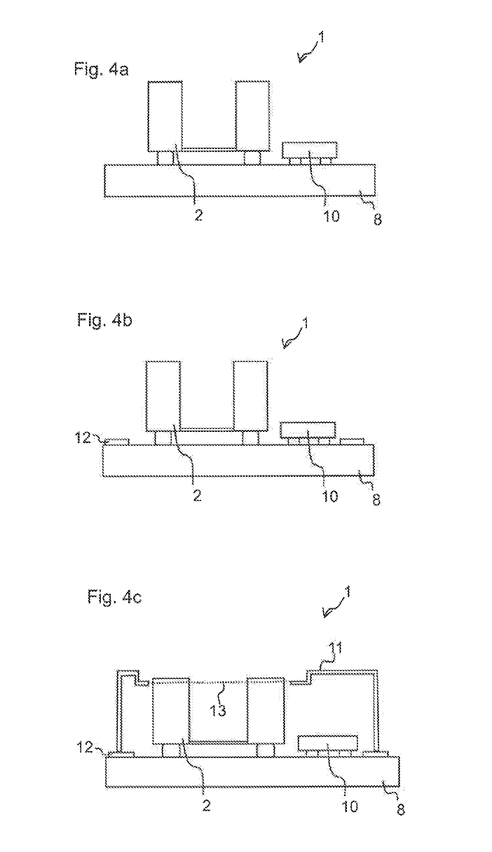

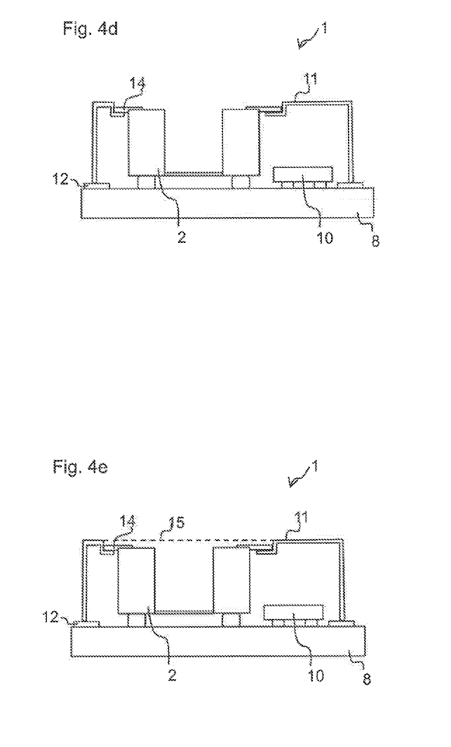

FIGS. 4a to 4e illustrate the method for producing a microphone 1 in accordance with the second exemplary embodiment.

FIG. 4a shows the microphone 1 after a method step in which the transducer element 2 and the further component 10 were fixed on the substrate 8. The transducer element 2 and the further component 10 are fixed on the substrate 8 in each case using flip-chip technology.

FIG. 4b shows the microphone 1 after a further method step in which the conductive adhesive 12 was applied on the substrate 8.

FIG. 4c shows the microphone 1 after a further method step in which the cover 11 was fixed to the conductive adhesive 12. The cover 11 can be fixed on the substrate 8 by adhesive bonding. Alternatively, the cover 11 can also be fixed on the substrate 8 by soldering. The cover 11 is fixed on the substrate 8 such that the opening 13 of the cover 11 completely covers the transducer element 2.

FIG. 4d shows the microphone 1 after a further method step in which an adhesive was applied between the cover 11 and the transducer element 2. The adhesive was subsequently cured to form the sound separation 14. The sound separation 14, the cover 11, the substrate 8 and the transducer element 2 now enclose the back volume 6 of the transducer element 2.

FIG. 4e shows the microphone 1 after a last method step in which the sound-transmissive protective grille 15 was fixed above the opening 13 of the cover 11. The sound-transmissive protective grille 15 can be fixed on the cover 11 for example by an adhesive-bonding connection.

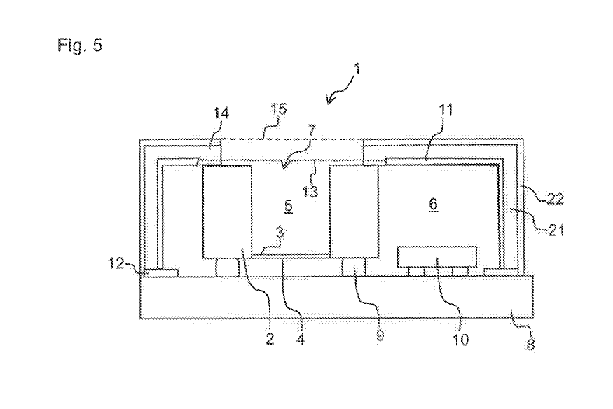

FIG. 5 shows a fourth exemplary embodiment of the microphone 1. In the fourth exemplary embodiment, the sound separation 14 does not comprise an adhesive, but rather a film 21. The film 21 is arranged in such a way that it partly covers the cover 11 and the transducer element 2 and in the process fixes the cover 11 to the transducer element 2. The film 21 covers the side walls 16 of the cover 11. Furthermore, the film 21 covers the regions of the top side 17 of the cover 11 which are free of the opening 13.

The film 21 consists of a polymer. This likewise involves a very soft material that is configured to absorb forces acting on the microphone 1 and thus to mechanically decouple the cover 11 from the transducer element 2.

In particular, the sound separation 14 comprises a layer stack. The layer stack furthermore comprises, alongside the film 21, a metal layer 22 arranged above the film 21 composed of polymer. The metal layer 22 is reinforced electrolytically. The metal layer 22 can comprise copper and nickel.

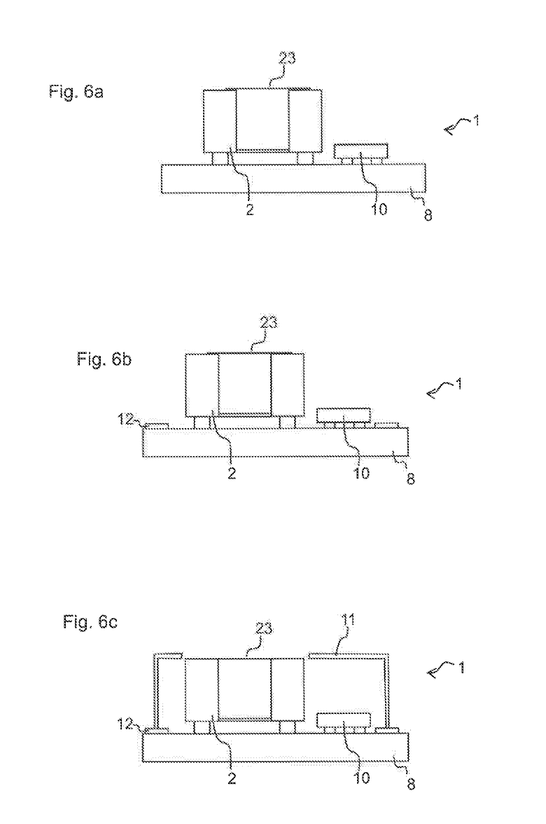

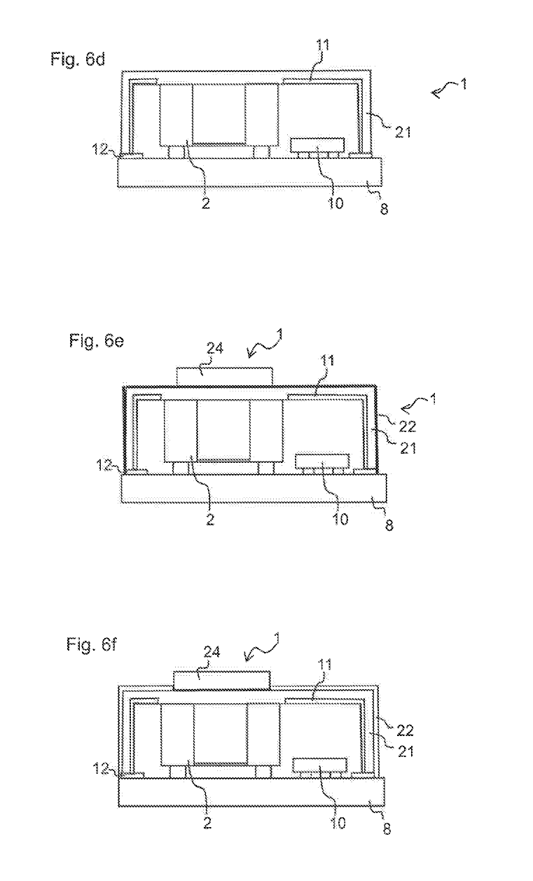

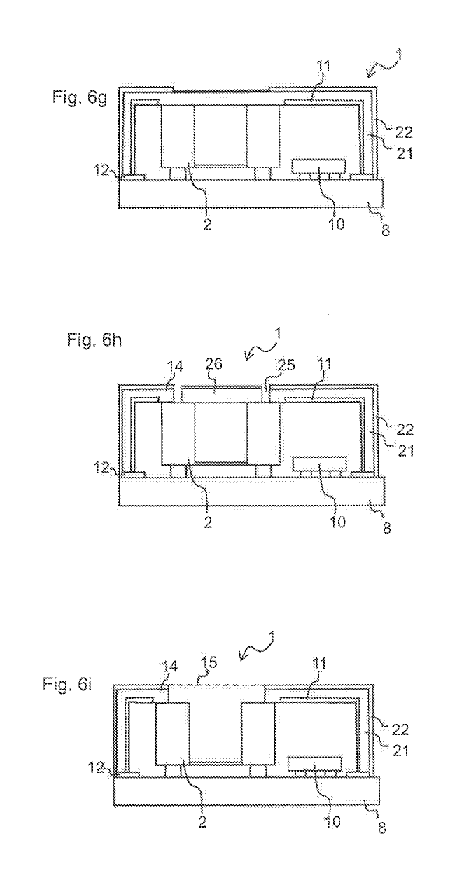

FIGS. 6a to 6i show the method for producing a microphone 1 in accordance with the fourth exemplary embodiment.

FIG. 6a shows the microphone 1 after the transducer element 2 and the further component 10 have been fixed on the substrate 8. A protective film 23 is arranged on the top side of the transducer element 2 facing away from the substrate 8 and is configured to the effect that the film 21 is applied on the protective film 23 in a later method step. The protective film 23 can be removed again in a later method step.

FIG. 6b shows the microphone 1 after the conductive adhesive 12 was applied on the substrate 8.

FIG. 6c shows the microphone 1 after the cover 11 was adhesively bonded on the adhesive 12.

FIG. 6d shows the microphone 1 after a further method step. In this further method step the sound separation 14 was produced by the film 21 having been applied on the side walls 16 and the top side 17 of the cover 1 and also on the transducer element 2. The film 21 now mechanically connects the cover 11 to the transducer element 2. Furthermore, at this point in time of the method the film 21 closes the opening 13 in the cover 11.

FIG. 6e shows the microphone 1 after a further method step. Firstly the metal layer 22 was applied over the whole area on the film 21. Afterward a photoresist structure 24 was applied. The photoresist structure 24 was applied in the region in which the film 21 is removed in a later method step.

FIG. 6f shows the microphone 1 after a further method step in which the metal layer 22 was reinforced electrolytically.

FIG. 6g shows the microphone 1 after a further method step in which the photoresist structure 24 was removed.

FIG. 6h shows the microphone 1 after a further method step in which a circumferential cut 25 was produced in the film 21 by means of a laser. The cut 25 separates an inner region 26 of the film 21 from the rest of the film 21. The cut 25 was in the opening 13 of the cover 11.

FIG. 6i shows the microphone 1 after a further method step in which the separated inner region 26 of the film 21 was removed. As a result, an opening is formed in the film 21. The opening in the film 21 overlaps the sound entrance opening 7 of the transducer element 2. The separated inner region 26 was pulled off. Furthermore, the sound-transmissive protective grille 15 was applied on the microphone 1.

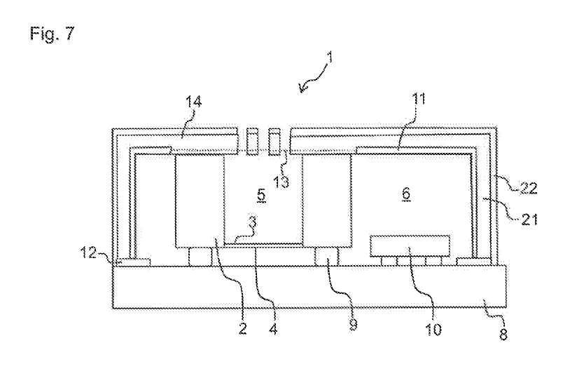

FIG. 7 shows the microphone 1 in accordance with a fifth exemplary embodiment. The fifth exemplary embodiment differs from the fourth exemplary embodiment in that the opening produced in the film 21 is smaller than the sound entrance opening 7 of the transducer element 2. In particular, here a plurality of openings forming a grille-like region was produced in the film 21. The grille-like region of the film 21 can be produced by the corresponding cutting of the film 21 by means of lasers and extraction of the regions cut out.

FIGS. 5 and 7 show the fourth and fifth exemplary embodiments in each case with a cover 11 having a flat top side 17. However, the fourth and fifth exemplary embodiments can also be combined with the second or third exemplary embodiment, such that the cover 11 can have first and second regions 18, 19 offset relative to one another and/or depressions 20 facing toward the substrate 8. What is common to all the exemplary embodiments is that the opening 13 in the cover 11 does not overlap the transducer element 2.

1-15. (canceled)

16. A microphone comprising:
a substrate;
a transducer element arranged on the substrate;
a cover having an opening, wherein the opening of the cover completely covers the transducer element; and
a sound separation fixing the cover to the transducer element.

17. The microphone according to claim 16, wherein the transducer element forms a front volume and a back volume, wherein the front volume is acoustically connected to surroundings of the microphone via the opening of the cover, and wherein the cover and the sound separation are arranged such that the cover, the sound separation, the transducer element and the substrate enclose a back volume of the transducer element.

18. The microphone according to claim 16, wherein the cover comprises metal.

19. The microphone according to claim 16, wherein the sound separation comprises a material having a lower modulus of elasticity than the cover.

20. The microphone according to claim 16, wherein the sound separation comprises an adhesive.

21. The microphone according to claim 16, wherein the cover has a top side arranged parallel to the substrate, and wherein the opening of the cover is arranged in the top side.

22. The microphone according to claim 21, wherein the top side of the cover has a first region and a second region, wherein the opening is arranged in the first region, and wherein the first region is at a smaller distance from the substrate than the second region.

23. The microphone according to claim 21, wherein the top side has a depression facing toward the substrate.

24. The microphone according to claim 16, wherein the sound separation comprises a film completely covering the cover and partly covering the transducer element.

25. The microphone according to claim 24, wherein the film essentially consists of a polymer.

26. The microphone according to claim 24, wherein a metal layer is arranged above the film.

27. The microphone according to claim 16, wherein the transducer element has a sound entrance opening that is free of the sound separation.

28. The microphone according to claim 16, wherein the transducer element has a sound entrance opening that is partly covered by the sound separation.

29. The microphone according to claim 28, wherein the sound separation has a grille-shaped region that partly covers the sound entrance opening.

30. The microphone according to claim 16, wherein a sound-transmissive protective grille is arranged above the opening of the cover.

31. The microphone according to claim 16, wherein the sound separation directly fixes the cover to the transducer element.

32. A microphone comprising:
a substrate;
a transducer element arranged on the substrate;
a cover having an opening, wherein the opening of the cover completely covers the transducer element; and
a sound separation fixing the cover to the transducer element,
wherein the cover has a top side arranged parallel to the substrate,
wherein the opening of the cover is arranged in the top side,
wherein the top side of the cover has a first region and a second region,
wherein the opening is arranged in the first region, and
wherein the first region is at a smaller distance from the substrate than the second region.
